(19) United States
(12) Patent Application Publication
(10) Pub. No.: US 2022/0037541 A1
(43) Pub. Date: Feb. 3, 2022

(54) FLEXIBLE SOLAR ARRAY FOR EXTRATERRESTRIAL DEPLOYMENT

(71) Applicant: Northrop Grumman Systems Corporation, Falls Church, VA (US)

(72) Inventors: Mark A. Kruer, Rolling Hills Estate, CA (US); Jud J. Yamane, Torrance, CA (US)

(21) Appl. No.: 16/943,440

(22) Filed: Jul. 30, 2020

(51) Int. Cl. H01L 31/0216; H01L 31/0392; H01L 31/18; H01G 9/20; H01G 9/00

(52) U.S. Cl. CPC H01L 31/02168; H01L 31/03928; H01G 9/0029; H01G 9/209; H01G 9/2095; H01L 31/18

(57) ABSTRACT

A flexible solar array for extraterrestrial deployment and a method of manufacturing such a flexible solar array are disclosed. A power generating layer, a durable layer, and an ultraviolet radiation blocking layer are disposed such that durable layer is between the power generating layer and the ultraviolet radiation blocking layer.

### FIELD OF DISCLOSURE

The present subject matter relates to flexible solar arrays, and more particularly, to a flexible solar array for extraterrestrial deployment and a method of the manufacturing same.

### BACKGROUND

Flexible solar arrays have been developed for portable and/or recreational terrestrial applications. Such flexible solar arrays typically have a flexible substrate, solar cells disposed on the substrate, and conductive connections to transfer electrical power generated by the solar cells to a device to be powered or an electrical storage device such as a battery.

However, flexible solar arrays designed for terrestrial applications may not be suitable for extraterrestrial use because the components of such solar arrays may not be sufficiently durable to survive harsh conditions present in an extraterrestrial environment. For example, a solar array deployed in an extraterrestrial environment must be able to withstand or be immune to the effects of very low temperatures, exposure to high levels of ultraviolet radiation, buildup of electric charge that may occur when the solar array is transported through the Van Allen belts that surround the earth's atmosphere, and bombardment by sub-atomic particles ejected from the sun and the like.

Further, because space available in transport vehicles is limited, the solar array may have to be rolled and/or folded into a compact package during transport into the extraterrestrial environment. A solar array designed for terrestrial use may not be sufficiently durable to withstand such rolling and/or folding without damaging (e.g., shorting, cracking, etc.) the components thereof.

### SUMMARY

According to one aspect, a flexible solar array for extraterrestrial deployment includes a power generating layer, a durable layer, and an ultraviolet radiation blocking layer. The durable layer is disposed between the power generating layer and the ultraviolet radiation blocking layer.

According to another aspect, a method of manufacturing a flexible solar array for extraterrestrial deployment includes the steps of providing a power generating layer that comprises a base layer and a plurality of solar cells disposed on the base layer and disposing a durable layer on top of the power generating layer such that the plurality of solar cells is disposed between the base layer and the durable layer. The method includes the additional step of disposing an ultraviolet radiation blocking layer on top of the durable layer such that the durable layer is between the power generating layer and the ultraviolet radiation blocking layer.

Other aspects and advantages will become apparent upon consideration of the following detailed description and the attached drawings wherein like numerals designate like structures throughout the specification.

### BRIEF DESCRIPTION OF THE DRAWINGS

FIG. 1 is a planar view of a flexible solar array;

FIG. 2 is sectional view of the flexible solar array of FIG. 1 taken generally along the line 2-2; and

FIG. 3 is an isometric view of the flexible solar array of FIG. 1 disposed on a spool.

### DETAILED DESCRIPTION

A flexible solar array is disclosed herein that is suitable for use in extraterrestrial applications. The flexible solar array includes a flexible power generating layer comprising solar cells formed of a photovoltaic material on a flexible substrate, a layer of a flexible durable polyester film layer, e.g., Mylar, is disposed on top of the power generating layer, and a pure or doped transparent layer of zinc oxide (ZnO) is deposited atop the layer of the durable polyester film. As described further below, the layer of the durable polyester film and the layer of ZnO combine to protect the solar cells during preparation and testing of the flexible solar array on earth, transport of the flexible solar array into space for deployment, and the hazards of the extraterrestrial environment after deployment.

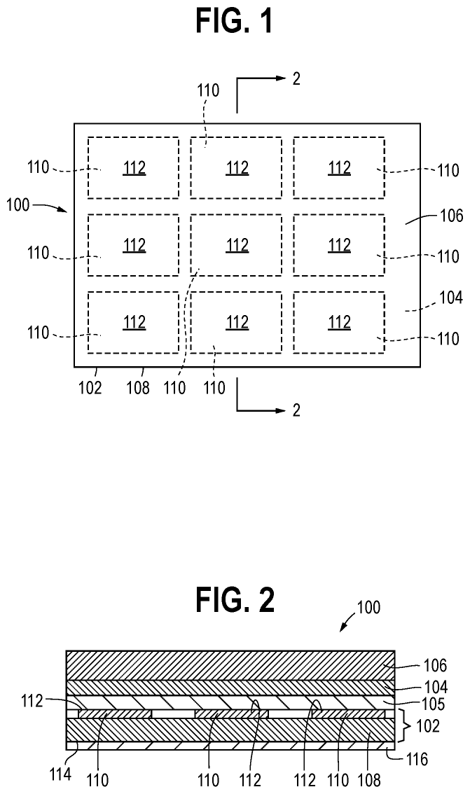

Referring to FIGS. 1 and 2, a flexible solar array 100 comprises a power generating layer 102, a durable layer 104 disposed atop the power generating layer 102, and an ultraviolet blocking layer 106 disposed atop the durable layer 104.

Further, the power generating layer 102 comprises a base layer 108 having a plurality of solar cells 110 disposed thereon. Although FIG. 1 illustrates a flexible solar array 100 having 9 solar cells 110 disposed on the base layer 108, it should be apparent to one who has ordinary skill in the art that the flexible array 100 may comprise fewer or more solar cells 110. Each solar cell 110 comprises a photovoltaic material and associated conductors (not shown for clarity) for conducting electricity generated by the solar cell 110 to a load (not shown) powered by the flexible solar array 100. A variety of photovoltaic materials may be selected for use in the solar cell 110 including copper indium gallium selenide (CIGS), cadmium telluride, perovskites, and semiconductors such as silicon either in crystalline or amorphous form, and the like.

The base layer 108 may be selected in accordance with the photovoltaic material selected to comprise the solar cell 110 including a metal, glass, or a polymer. For example, a metal such as stainless steel may be preferred for the base layer 108 if the photovoltaic material comprising the solar cell 110 is CIGS. Alternately, glass may be selected for the base layer 108 if the photovoltaic material is cadmium telluride. In a preferred embodiment, the power generating layer 102 comprises solar cells 110 made of amorphous silicon because, as one of ordinary skill in the art would appreciate, amorphous silicon is impervious to damage by charged particles such as those present in the Van Allen belts considering normal operating temperatures around earth and does not degrade when exposed to residual ultraviolet radiation under the ZnO coating of the ultraviolet blocking layer 106. In such preferred embodiment, the amorphous silicon is deposited on a base layer 108 that is a Kapton film, manufactured by the DuPont de Nemours, Inc. of Wilmington Del. Kapton is a preferred material for the base layer 108 because Kapton is sufficiently impervious to ultraviolet radiation and durable to protect the solar cells 110 disposed thereon. Further, Kapton retains its properties (such as durability and resistance to ultraviolet radiation) even when disposed in environments that have high levels of ultraviolet radiation, very cold temperatures, and/or very hot temperatures. In some embodiments the Kapton film has a thickness of between about 7 microns and about 76 microns. Other materials that are durable and are impervious to high levels of ultraviolet radiation and/or large variations in temperature apparent to one who has ordinary skill in the art may be used instead of Kapton.

In some embodiments, the amorphous silicon is deposited onto the Kapton film or another material that comprises the base layer 108 by sputtering. It should be apparent to one who has ordinary skill in the art that other ways of applying the photovoltaic material onto the base layer 108 to form the solar cell 110 may be used.

The durable layer 104 provides a protective coating over the power generating layer 102 that prevents damage to the components (e.g., the solar cells 110) of the power generating layer 102 and that may be transported into space. For example, to transport the flexible solar array 100 into space, the flexible solar array 100 may be rolled or folded compactly to minimize the volume occupied thereby. Without the protection provided by the durable layer 104, during such folding or rolling, a first outer surface 112 of a first solar cell 110 may contact a second outer surface 112 of a second solar cell 110. Such contact may cause electrical shorting, abrasion, or other damage to one or both of the first and second solar cells 110.

In addition, the durable layer 104 prevents damage to components of the power generating layer 102 that may occur if such components contact and/or are struck by other objects during manufacture, testing, and/or transport such as testing equipment, fixtures that hold the flexible solar array 100, tools used to secure the flexible solar array 100 to fixtures, and the like. The durable layer 104 comprises a flexible, durable, transparent or translucent, polymer film such as Kynar manufactured by Arkema S. A. of Colombe, France, Mylar manufactured by DuPont Teijin Films of Hopewell, Va., and the like.

The durable layer 104 should be sufficiently transparent to the wavelengths of light that cause the solar cell 110 to generate electrical current. In some embodiments, the durable layer 104 is sufficiently transparent that at least 80% of the light to which the durable layer is exposed is transmitted therethrough and impinges the solar cell 110. In other embodiments, less transmission may be acceptable considering the operating temperature and high radiation dose present in some orbits. For example, the durable layer 104 may be highly transparent when the flexible solar array 100 is first deployed but may become translucent (i.e., less transparent) over time if deployed in an orbit in which the flexible solar array 100 is exposed to high levels of radiation and/or suboptimal temperatures.

In a preferred embodiment, the material selected for the durable layer 104 and the material selected for the base layer 108 have similar coefficients of expansion to prevent unwanted curling of the flexible solar array 100 when the flexible solar array 100 is heated or cooled. In a preferred embodiment, the base layer 108 comprises Kapton and the durable layer 104 comprises Mylar.

In some embodiments, the Mylar selected for the durable layer 104 and the Kapton selected for the base layer 108 have coefficients of expansion at room temperature of about 17 parts per million per degree Celsius. In some embodiments, these materials may be pre-shrunk prior to use in the solar array 100. In a preferred embodiment, the durable layer 104 and the base layer are selected to have coefficients of expansion to avoid curling of the flexible solar array 100 of more than about 10 degrees out-of-plane pointing due to temperature changes.

In one embodiment, the durable layer 104 is secured to the power generating layer 102 using an adhesive layer 105 that comprises, for example, a polyethylene adhesive, silicone-based adhesive, epoxy-based adhesive, fluoropolymer-based adhesive, and the like. In some embodiments, the durable layer 104 may comprise a material that enables securement of the durable layer 104 to the power generating layer 102 without the use of an adhesive and in such embodiments the adhesive layer 105 is not used. For example, a material such as Kynar may be used for the durable layer 104 that can be applied to the power generating layer 102 by, for example, melting and pressing such material onto the power generating layer 102 using a lamination process. Other ways of securing the durable layer 104 to the power generating layer 102 apparent to one who has ordinary skill in the art may be used.

As would be apparent to one who has ordinary skill in the art, polymer materials selected for the durable layer 104 may be damaged by exposure to a large amount of ultraviolet radiation. The ultraviolet radiation blocking layer 106 is disposed atop the durable layer 104 to prevent such exposure and resulting damage. In a preferred embodiment, the ultraviolet radiation blocking layer 106 comprises ZnO applied to the polymer film that comprises the durable layer 104. In some embodiments, the ultraviolet radiation blocking layer 106 is formed by applying a layer ZnO to the durable layer 104 by sputtering. It should be apparent to one who has ordinary skill in the art that another technique may be utilized to apply ZnO to the durable layer 104 to form the ultraviolet radiation blocking layer 106.

In some embodiments, the ultraviolet radiation blocking layer 106 is made electrically conductive by, for example, applying a layer of ZnO that is sufficiently thick to become conductive or doping the ZnO that comprises the ultraviolet radiation blocking layer 106 with another material such as aluminum. Having an electrically conductive ultraviolet radiation blocking layer 106 dissipates charge that may build when the flexible solar arrayl00 is transported through the charged particles that comprise the Van Allen belts that surround the earth. In some embodiments, the ultraviolet radiation blocking layer 106 comprises a conductive layer of undoped ZnO having a thickness of between about 30 nanometers and about 110 nanometers.

In some embodiments, the external surface 114 of the base layer 108 is coated with a layer of conductive material 116 such as a conductive oxide, a thin metal, corrosion-resistant steel (CRES), and the like. Such layer of conductive material 116 and the ultraviolet radiation blocking layer 106 may be conductively coupled to electrical ground (e.g., a frame on which the solar array is disposed and the like) to minimize accumulation of static charge in the solar array 100 and/or facilitate dissipation of such static charge.

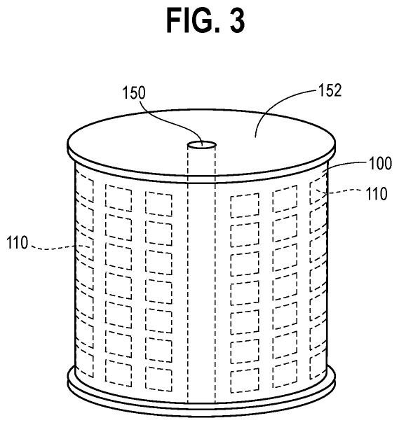

Referring to FIG. 3, in some embodiments, for transport in a space vehicle, the flexible solar array 100 is rolled about a spindle 150 of a drum 152. In some cases, the flexible solar array 100 may be folded before being rolled about the spindle 150. After the flexible solar array 100 is transported into the extraterrestrial environment, the flexible solar array 100 may be deployed by unrolling and, if necessary, unfolding the flexible solar array 100 and securing portions thereof to support structures (not shown) and disposing the flexible solar array 100 such that the solar cells 110 of the flexible solar array 100 face the sun to generate electrical power.

In some embodiments, the flexible solar array 100 disclosed herein has a width between about 5 meters and 40 meters and a length between about 5 meters and 40 meters. It should be apparent that the flexible solar array 100 may have smaller or larger than these dimensions. In one embodiment, the flexible solar array 100 is 15 meters by 15 meters and, when folded and rolled for stowage, occupies a volume of approximately 33 liters.

Although the flexible solar array 100 shown in FIG. 1 is generally rectangular, it should be apparent to one who has ordinary skill in the art that the flexible solar array 100 may have any shape including elliptical, circular, triangular, polygonal, and the like. Further, the solar array 100 may be manufactured by joining smaller solar panels (not shown), each comprising the power generating layer 102, the durable layer 104, and the ultraviolet radiation blocking layer 106. Such solar panels may be joined to one another using an adhesive, by sewing, or any other joining method apparent to one who has ordinary skill in the art. In addition, it should be apparent that the flexible solar array 100 may comprise additional layers (not shown) to improve the performance and/or durability of the flexible solar array 100.

In one embodiment, the flexible solar array 100 comprises a durable layer 104 of Mylar that is about 25.4 microns thick and a base layer 108 that is about 38.1 microns thick. Such durable layer 104 is secured to the power generating layer 102 by an adhesive layer 105 of polyethylene adhesive that is about 12.5 microns thick. In such flexible solar array 100, a conductive layer 116 that comprises CRES and is about 30 nanometers thick is disposed on the outer surface 114 of the base layer 108 and a layer of ZnO that is about 30 nanometers thick is disposed on top of the durable layer 104 of Mylar.

### INDUSTRIAL APPLICABILITY

The flexible solar array 100 disclosed herein provides a cost-effective, flexible, and compactable flexible solar array 100. The durable layer 104 of the flexible solar array 100 protects the power generation layer 102 from physical damage, and the ultraviolet radiation blocking layer 106 protects the durable layer 104 from degradation by ultraviolet radiation. The flexible solar array 100 may be folded, rolled into a cylinder, or rolled onto a spool to form a compact package that is suitable for transport from the earth to space without damage.

The materials used for the different layers 104, 105, 106, 108, 110, 114, and 116 that comprise the flexible solar array 100 disclosed herein are commercial materials that are already used in terrestrial applications. Thus, the cost of the flexible solar array 100 that uses such materials and is suitable for extraterrestrial use may have a cost that is substantially less than that of an alternative flexible solar array that uses unique or exotic materials especially designed for extraterrestrial applications.

Numerous modifications to the present disclosure will be apparent to those skilled in the art in view of the foregoing description. It should be understood that the illustrated embodiments are exemplary only and should not be taken as limiting the scope of the disclosure.

1. A flexible solar array for extraterrestrial deployment, comprising:
a power generating layer;
a durable layer; and
an ultraviolet radiation blocking layer, wherein the ultraviolet radiation blocking layer is electrically conductive and coupled to electrical ground;
wherein the durable layer is disposed between the power generating layer and the ultraviolet radiation blocking layer and the ultraviolet radiation blocking layer is coupled to electrical ground.

2. The flexible solar array of claim 1, wherein the power generating layer comprises a base layer and a plurality of solar cells disposed on the base layer.

3. The flexible solar array of claim 2, wherein the base layer comprises one of Kapton, a metal, glass, and a polymer.

4. The flexible solar array of claim 2, wherein the plurality of solar cells comprises one of copper indium gallium selenide, cadmium telluride, perovskites, or a semiconductor.

5. The flexible solar array of claim 2, wherein the durable layer and the base layer have coefficients of expansion that are similar.

6. The flexible solar array of claim 1, wherein the durable layer comprises a transparent or translucent polymer film.

7. The flexible solar array of claim 6, wherein the durable layer is adhesively secured to the power generating layer.

8. The flexible solar array of claim 1, wherein the ultraviolet radiation blocking layer comprises zinc oxide.

9. The flexible solar array of claim 1 in combination with a spool, wherein the flexible solar array is rolled about a spindle of the spool.

10. The flexible solar array of claim 1, wherein the power generating layer comprises Kapton, the durable layer comprises Mylar, and the ultraviolet radiation blocking layer comprises zinc oxide.

11. The flexible solar array of claim 1, further including an electrically conductive layer secured to the base layer, wherein the electrically conductive layer is coupled to electrical ground.

12. A method of manufacturing a flexible solar array for extraterrestrial deployment, comprising:
providing a power generating layer that comprises a base layer and a plurality of solar cells disposed on the base layer;
disposing a durable layer on top of the power generating layer such that the plurality of solar cells is disposed between the base layer and the durable layer; and
disposing an ultraviolet radiation blocking layer on top of the durable layer such that the durable layer is between the power generating layer and the ultraviolet radiation blocking layer, wherein the ultraviolet radiation block layer is electrically conductive and coupled to electrical ground.

13. The method of claim 12, wherein the base layer comprises one of Kapton, a metal, glass, and a polymer;

14. The method of claim 13, wherein the step of providing the power generating layer comprises disposing one of copper indium gallium selenide, cadmium telluride, perovskites, or a semiconductor on the base layer.

15. The method of claim 12, wherein the step of disposing the durable layer comprises the step of disposing the durable layer that has a coefficient of expansion similar to that of the base layer.

16. The method of claim 12, wherein the step of disposing the durable layer comprises the step of disposing a transparent or translucent polymer film.

17. The method of claim 13, wherein the step of disposing the durable layer comprises the step of adhesively securing the durable layer to the power generating layer.

18. The method of claim 12, wherein disposing the ultraviolet radiation blocking layer comprises the step of disposing zinc oxide.

19. The method of claim 12, further comprising the step of rolling the flexible array about a spindle of a spool.

20. The method of claim 12, wherein the power generating layer comprises Kapton, the durable layer comprises Mylar, and the ultraviolet radiation blocking layer comprises zinc oxide.
